(19) United States
(12) Patent Application Publication
(10) Pub. No.: US 2007/0251675 A1
(43) Pub. Date: Nov. 1, 2007

(54) THERMAL MODULE

(75) Inventors: CHING-BAI HWANG, TU CHENG (TW); JIN-GONG MENG, Shenzhen (CN); JIE-BO PENG, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., TU CHENG (TW)

(21) Appl. No.: 11/308,726

(22) Filed: Apr. 26, 2006

(51) Int. Cl. H05K 7/20

(52) U.S. Cl. 165/104.33; 165/104.21; 361/700; 257/715

(57) ABSTRACT

A thermal module (10) for dissipating heat from a heat-generating electronic component includes a fin assembly (12), and a heat pipe (14) including an evaporator section (141) and a curve shaped condenser section (142). The evaporator section of the heat pipe thermally contacts with the heat-generating electronic component, and the condenser section of the heat pipe is disposed on the fin assembly along a longitudinal axis of the fin assembly. The condenser section has a serpentine configuration.

### FIELD OF THE INVENTION

The present invention relates generally to a thermal module, and more particularly to a thermal module for dissipating heat generated by electronic components.

### DESCRIPTION OF RELATED ART

Referring to FIG. 3, a thermal module 30 for dissipating heat generated by a heat generating electronic component includes a base plate 31 contacting with the heat generating component, a heat pipe 34 including an evaporator section 341 contacting with the base plate 31, a fin assembly 32 contacting with a linear shaped condenser section 342 of the heat pipe 34, and a heat dissipating fan 33 for driving an airflow flowing through the fin assembly 32 to take heat away.

In operation of the thermal module 30, the base plate 31 absorbs heat from the heat generating component, and transfers the heat to the evaporator section 341 of the heat pipe 34. The evaporator section 341 of the heat pipe 34 transmits the heat to the condenser section 342 of the heat pipe 34 via the evaporation and condensation of the working medium in the heat pipe 34. Then, the heat is transferred to the fin assembly 32 and taken away by the airflow passing through air channels formed between two adjacent fins. Thus, the heat dissipation of the heat-generating component is accomplished.

During the operation of the thermal module 30, the size of contact area between the condenser section 342 of the heat pipe 34 and the fin assembly 32 directly affects the heat dissipation efficiency of the thermal module 30. An effective way to improve the heat dissipation efficiency of the thermal module 30 is to increase the contacting area between the condenser section 342 of the heat pipe 34 and the fin assembly 32. Generally, the heat pipe 34 is flattened to satisfy such requirement. Moreover, the flattened heat pipe 34 can reduce a height of the thermal module 30 whereby the thermal module 30 can be more suitably used in a laptop computer, which is required to have a profile as small as possible. Since the condenser section 342 of the heat pipe 34 is linear shaped, such way of increasing the contact area does not increase the heat dissipation efficiency of the thermal module 30 enough the meet the more and more demanding requirement of heat dissipation for up-to-date laptop computers. Thus, a thermal module which can further increase the contact area between the condenser section 342 of the heat pipe 34 and the fin assembly 32 is needed.

### SUMMARY OF INVENTION

The present invention relates to a thermal module for dissipating heat from a heat-generating electronic component. According to a preferred embodiment of the present invention, the thermal module includes a fin assembly, and a heat pipe including an evaporator section and a curve shaped condenser section. The evaporator section of the heat pipe thermally contacts with the heat-generating electronic component, and the condenser section of the heat pipe is disposed on the fin assembly along a longitudinal direction of the fin assembly. The curve shaped condenser section increases thermal contact area between the heat pipe and the fin assembly, thereby increasing heat dissipation efficiency of the thermal module.

Other advantages and novel features of the present invention will become more apparent from the following detailed description of preferred embodiment when taken in conjunction with the accompanying drawings, in which:

### BRIEF DESCRIPTION OF DRAWINGS

FIG. 1 is an exploded, isometric view of a thermal module according to a preferred embodiment of the present invention;

FIG. 2 is an assembled view of the thermal module of FIG. 1; and

FIG. 3 is an assembled view of a thermal module according to prior related art.

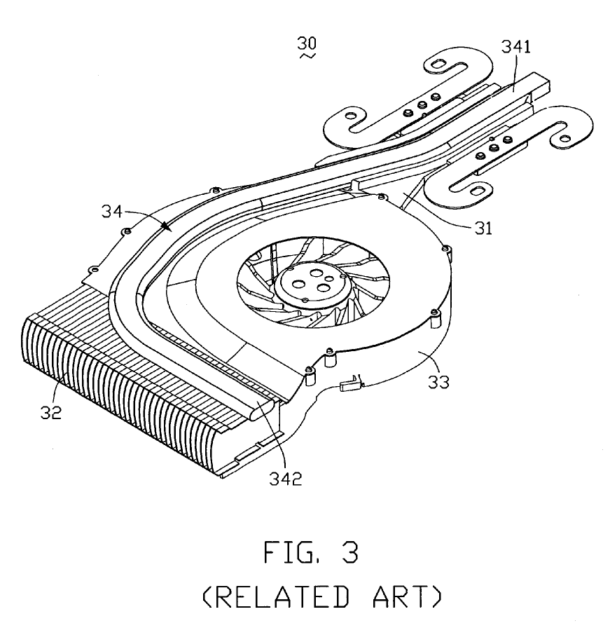

### DETAILED DESCRIPTION

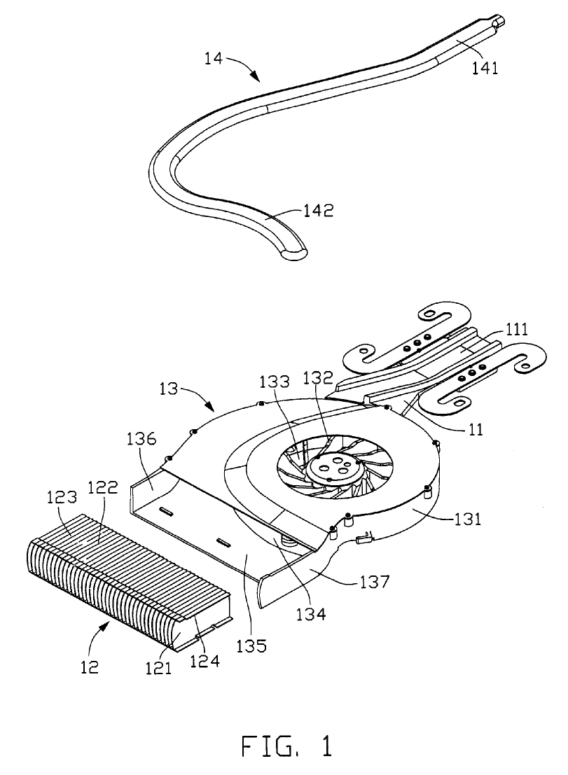

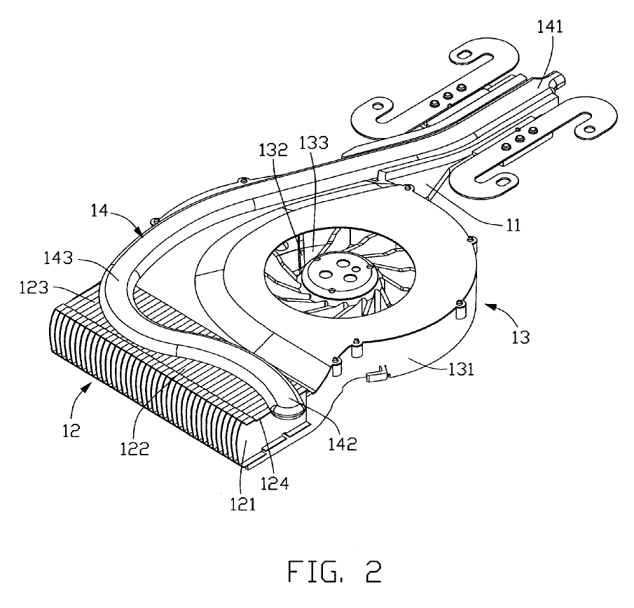

Referring to FIGS. 1 and 2, a thermal module 10 according to a preferred embodiment of the present invention is shown. The thermal module 10 includes a base plate 11, a flattened heat pipe 14, a fin assembly 12, and a heat-dissipating fan 13.

The base plate 11 is made of materials having good heat conductivity, such as copper or aluminum, and defines a groove 111 for receiving the heat pipe 14 therein. The base plate 11 has a bottom surface contacting with a heat generating electronic component (not shown), and a top surface contacting with the heat pipe 14.

The heat-dissipating fan 13 is a centrifugal blower connected with an end of the base plate 11 for providing a high-pressure airflow. The heat-dissipating fan 13 includes a casing 131, a stator (not shown) mounted in the casing 131, and a rotor 132 rotatably disposed around the stator. An air inlet 133 is defined in a top wall of the casing 131, while an air outlet 134 is defined in a sidewall of the casing 131 perpendicular to the air inlet 133. A supporting plate 135 extends from a bottom wall of the casing 131 at the air outlet 134 of the heat-dissipating fan 13 to support the fin assembly 12. When the heat-dissipating fan 13 is activated, the rotor 132 rotates in a counterclockwise direction when viewed from the top wall of the heat-dissipating fan 13 of FIG. 1. Thus, the airflow leaves the heat dissipating-fan 13 at a left side 136 of the air outlet 134 and flows toward a right side 137 of the air outlet 134. The airflow adjacent to the left side 136 of the air outlet 134 has a higher air pressure and a faster air velocity than the airflow adjacent to the right side 137 of the air outlet 134 due to the kinetic energy loss of the airflow.

The fin assembly 12 is mounted to the supporting plate 135 of the heat dissipating fan 13. The fin assembly 12 is stacked by a plurality of fins 121 parallel to each other, and includes an end 123 adjacent to the left side 136 of the air outlet 134 of the heat-dissipating fan 13. Each of the fins 121 perpendicularly extends a flange 124 at a top and a bottom portion thereof. The fins 121 are arranged along a longitudinal direction of the supporting plate 135 of the heat-dissipating fan 13, with the flanges 124 of a left fin 121 abutting against a body of a right fin 121. A supporting surface 122 is formed on a top surface of the fin assembly 12 by the flanges 124 of the fins 121.

The heat pipe 14 is mounted on the fin assembly 12 with a bottom surface thereof intimately contacting with the supporting surface 122 of the fin assembly 12. The heat pipe 14 includes an evaporator section 141 received in the groove 111 of the base plate 11, and a curve shaped condenser section 142 contacting with the fin assembly 12. The configuration of the condenser section 142 according to this preferred embodiment is “S” shaped with two arcs. Alternatively, the condenser section 142 can be serpentine with more than two arcs. The condenser section 142 of the heat pipe 14 includes an arc shaped bending portion 143 formed thereon. The bending portion 143 is disposed adjacent to the left side 136 of the air outlet 134 of the heat-dissipating fan 13, aligning with the end 123 of the fin assembly 12. In the present invention, interface materials such as thermal greases (not shown) are spread on both the top surface of the base plate 11 and the supporting surface 122 of the fin assembly 12, so as to maintain good thermal contact between the evaporator section 141 and the condenser section 142 of the heat pipe 14 and their attached base plate 11 and the fin assembly 12.

In operation of the thermal module 10, the base plate 11 absorbs heat from the heat-generating component, and transfers the heat to the evaporator section 141 of the heat pipe 14. The evaporator section 141 of the heat pipe 14 transmits the heat to the condenser section 142 of the heat pipe 14 via the evaporation and condensation of the working medium in the heat pipe 14. Then, the heat is transferred to the fin assembly 12 and taken away by the airflow passing through air channels formed between two adjacent fins 121. Thus, the heat generated by the heat-generating component is dissipated and a safe temperature maintained.

In the present invention, the condenser section 142 of the heat pipe 14 is bent so as to be “S” shaped, which increases a length of the condenser section 142 of the heat pipe 14 disposed on the fin assembly 12. This increases the thermal contact area between the heat pipe 14 and the fin assembly 12. Thus, the heat pipe 14 will transfer more heat directly to the fin assembly 12, thereby increasing heat dissipation efficiency of the thermal module 10. In the thermal module 10, the configuration and size of condenser section 142 of the heat pipe 14 is designed according to the size of the supporting surface 122 of the fin assembly 12, giving the largest possible contact area between the condenser section 142 of the heat pipe 14 and the fin assembly 12.

Compared to the heat pipe 34 of the related art, the “S” shaped condenser section 142 of the heat pipe 14 has greater contact area between the bending portion 143 of the heat pipe 14 and the end 123 of the fin assembly 12. This makes adequate use of the kinetic energy of the airflow adjacent to the left side 136 of the air outlet 134, further increasing the heat dissipation efficiency of the thermal module 10. The condenser section 142 has the bending portion 143 (i.e., first arc) extended to be proximate to a front edge of the fin assembly 12 distant from the fan 13, and the other bending portion (i.e., a second arc, not labeled) extended to be proximate to a rear edge of the fin assembly 12 close to the fan 13. Thus, the condenser section 142 can have an even contact with the fin assembly 12 to effectively dissipate the heat to the fin assembly 12.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A thermal module adapted for dissipating heat from a heat-generating electronic component comprising:
a fin assembly; and
a heat pipe comprising an evaporator section and a curve shaped condenser section, wherein the evaporator section thermally contacts with the heat-generating electronic component, and the condenser section is disposed on the fin assembly along a longitudinal direction of the fin assembly.

2. The thermal module as described in claim 1, wherein the configuration of the condenser section of the heat pipe is serpent-shaped with at least two arcs.

3. The thermal module as described in claim 1, further comprising a heat-dissipating fan for providing an airflow flowing through the fin assembly, the heat-dissipating fan defining an air outlet therein, the air outlet having a side from which the airflow leaves the heat dissipating-fan.

4. The thermal module as described in claim 3, wherein the heat-dissipating fan comprises a supporting plate extending from a bottom wall of the air outlet.

5. The thermal module as described in claim 3, wherein the fin assembly has an end adjacent to the side of the air outlet, the condenser section of the heat pipe has a bending portion aligned with the end of the fin assembly.

6. The thermal module as described in claim 5, wherein the bending portion has an arc shaped configuration.

7. The thermal module as described in claim 1, wherein the fin assembly comprises a supporting surface contacting with the condenser section of the heat pipe.

8. The thermal module as described in claim 1, wherein the condenser section of the heat pipe has a flattened cross section.

9. The thermal module as described in claim 1, wherein the heat-dissipating fan is a centrifugal blower.

10. A thermal module comprising:
a centrifugal blower defining an air outlet therein for allowing an airflow leaving the blower therefrom;
a fin assembly defining a plurality of air channels facing to the air outlet of the blower; and
at least a heat pipe comprising an evaporator section for thermally connecting with a heat-generating electronic component and a curve shaped condenser section contacting with a supporting surface of the fin assembly.

11. The thermal module as described in claim 10, further comprising a base plate connected to a sidewall of the blower, the base plate comprising a surface contacting with the heat-generating component, and an opposite surface contacting with the evaporator section of the heat pipe.

12. The thermal module as described in claim 10, wherein the blower comprises a supporting plate extending from a bottom wall thereof for contacting with an opposite surface of the fin assembly.

13. The thermal module as described in claim 10, wherein the condenser section of the heat pipe has a flattened cross section.

14. The thermal module as described in claim 10, wherein the configuration of the condenser section of the heat pipe is serpent-shaped with at least two arcs.

15. The thermal module as described in claim 10, wherein the fin assembly has an end adjacent to a side the airflow leaving from the air outlet, the condenser section of the heat pipe has a bending portion mounted on the end of the fin assembly.

16. The thermal module as described in claim 15, wherein the bending portion has an arc shaped configuration.

17. A thermal module comprising:
a base plate for thermally contacting with a heat-generating electronic component;
a fan for driving an airflow through an outlet thereof with a first part and a second part, wherein the airflow at the first part has more kinetic energy than at the second part;
a fin assembly having a plurality of fins stacked together along a direction from the first to the second parts of the air outlet of the fan; and
a heat pipe having an evaporator section thermally connecting with the base plate and a condenser section thermally connecting with the fins;
wherein the condenser section has a serpentine configuration with at least two arcs on the fins and extends along the direction.

18. The thermal module of claim 17, wherein one of the at least two arcs is located proximate to an edge of the fin assembly distant from the fan, and another of the at least two arcs is located proximate to an edge of the fin assembly close to the fan.

19. The thermal module of claim 18, wherein the one of the at least two arcs aligns with an end of the fin assembly which adjacent to the first part of the air outlet.

20. The thermal module of claim 17, wherein the condenser section of the heat pipe is disposed on the entire fin assembly along the direction.
